(19) United States
(12) Patent Application Publication
(10) Pub. No.: US 2005/0254310 A1
(43) Pub. Date: Nov. 17, 2005

(54) Nonvolatile semiconductor memory device including ferroelectric semiconductor pattern and methods for writing data in and reading data from the same

(75) Inventors: Jae Choon Lee, Seoul (KR); De Jun Fu, Seoul (KR); Tae Won Kang, Seoul (KR); Seung Joo Lee, Seoul (KR); Yoo Bum Heo, Pyungtaek-city (KR); Dae Hoon Kim, Namwon-city (KR); Ju Won Lee, Seoul (KR); Dong Jin Lee, Jeonju-city (KR)

Correspondence Address: FROMMER LAWRENCE & HAUG, 745 FIFTH AVENUE- 10TH FL., NEW YORK, NY, 10151, US

(73) Assignee: Dongguk University

(21) Appl. No.: 11/120,499

(22) Filed: May 3, 2005

(30) Foreign Application Priority Data
May 13, 2004 (KR) 10-2004-0033799

(51) Int. Cl. G11C 5/00

(52) U.S. Cl. 365/189.01

(57) ABSTRACT

Provided are a nonvolatile semiconductor memory device including ferroelectric semiconductor patterns in respective memory cells and methods of writing and reading data. The device includes a substrate; a plurality of first conductive lines disposed in or on the substrate; a plurality of second conductive lines disposed in or on the substrate and having a different height from the first conductive lines, wherein the second conductive lines intersect the first conductive lines, respectively, to define a plurality of intersection regions; and a plurality of memory cells disposed on the substrate. Herein, the memory cells include ferroelectric semiconductor patterns, respectively, which are disposed between the first conductive lines and the second conductive lines that define the intersection regions.

This application claims the priority of Korean Patent Application No. 10-2004-0033799, filed on May 13, 2004, in the Korean Intellectual Property Office, the disclosure of which is incorporated herein in its entirety by reference.

### BACKGROUND OF THE INVENTION

1. Field of the Invention

The present invention relates to a semiconductor memory device, and more particularly, to a nonvolatile semiconductor memory including ferroelectric semiconductor patterns in respective memory cells and methods of writing data in the memory cells and reading data from the memory cells.

2. Description of the Related Art

Semiconductor memory devices can be categorized into volatile memory devices and nonvolatile memory devices. Unlike the volatile memory devices, the nonvolatile memory devices can retain data even if power is not supplied. Some volatile memory devices, such as DRAMs or SRAMs, and some nonvolatile memory devices, such as EPROMs, EEPROMs, and flash EEPROMs, are being commonly used. However, the volatile memory devices are reaching a technical limit due to volatility of data. And, since the ERPOMs, EEPROMs, and flash EEPROMs, which are lowly integrated, operate at low speed, and/or require a high voltage, it is difficult to develop them into next generation memory devices.

To overcome the limit, laborious research for the commonly used memory devices has progressed in many colleges and laboratories. As a result, magnetic random access memories (MRAMs), phase change random access memories (PRAMs), and ferroelectric random access memories (FRAMs) were proposed as next generation semiconductor memories.

Among the above, an FRAM is a nonvolatile semiconductor memory device using a double stable polarization state of a ferroelectric material. As is known, each memory cell of the FRAM may have one of a variety of structures. For example, each memory cell of the FRAM may have a 1T(transistor)/1C(capacitor) structure in which a dielectric material used for a DRAM is superseded by a ferroelectric material, a 2T/2C structure in which data is read by comparing a 1T/1C type ferroelectric memory cell with a dummy memory cell, or a 1T structure in which a ferroelectric layer is used as a portion of a gate electrode structure of a transistor. Since a ferroelectric material, such as PZT, SLT, or, BLT, is substantially a dielectric material, no conducting effect caused by carriers occurs in ferroelectric layers.

There are materials that exhibit not only a similar stable double polarization state to that of ferroelectric materials such as PZT, SLT, and BLT but also semiconductivity. The materials are called ferroelectric semiconductor materials, such as CdZnTe, ZnCdS, CdMnTe, CdMnS, ZnCdSe, and CdMnSe. “Study of Ferroelectricity and Current-voltage Characteristics of CdZnTe” is disclosed in APPLIED PHYSICS LETTERS, Vol. 81, No. 27, 30 Dec. 2002 by D. J. Fu and J. C. Lee who is the inventor of the present application. This paper discloses a displacement versus electric field hysteresis loop and current-voltage characteristics of CdZnTe. The paper is completely combined with the present application by reference, as fully set forth in the application. Referring to the paper, it can be seen that ferroelectric semiconductor materials, such as CdZnTe, exhibit not only ferroelectricity but also semiconductivity.

### SUMMARY OF THE INVENTION

The present invention provides a memory cell of semiconductor memory devices which are highly integrated and nonvolatile. The present invention also provides a method of writing data in or reading data from the memory cell of semiconductor memory devices which are highly integrated and nonvolatile.

In the present invention, the nonvolatile semiconductor memory device is formed using a ferroelectric semiconductor material, which has both ferroelectricity and semiconductivity. The ferroelectric semiconductor material, which has a dielectric polarization, forms a hysteresis loop according to an electric field applied thereto. Thus, even if the applied electric field is removed, a double stable polarization state is maintained. Also, since the ferroelectric semiconductor material has semiconductivity, it functions as a resistor by free carriers included in crystalline lattices thereof. The ferroelectric semiconductor material as the resistor forms a Schottky contact or an ohmic contact at an interface with a metal layer. In particular, when the Schottky contact is formed at the interface between the ferroelectric semiconductor material and the metal layer, a contact resistance varies with a polarization state of the ferroelectric semiconductor material and a direction in which an electric field is applied thereto. The present invention utilizes a double characteristic of the ferroelectric semiconductor material.

According to an aspect of the present invention, there is provided a nonvolatile semiconductor memory device comprising: a substrate; a plurality of first conductive lines disposed in or on the substrate; a plurality of second conductive lines disposed in or on the substrate and having a different height from the height of the first conductive lines, wherein the second conductive lines intersect the first conductive lines, respectively, to define a plurality of intersection regions; and a plurality of memory cells disposed on the substrate, wherein the memory cells include ferroelectric semiconductor patterns, respectively, which are disposed between the first conductive lines and the second conductive lines that define the intersection regions. The ferroelectric semiconductor patterns may be formed of one selected from the group consisting of CdZnTe, ZnCdS, CdMnTe, CdMnS, ZnCdSe, and CdMnSe.

A Schottky contact may be formed at a contact surface between a ferroelectric semiconductor pattern and one of a first conductive line and a second conductive line, and an ohmic contact may be formed at a contact surface between the ferroelectric semiconductor pattern and the other of the first conductive line and the second conductive line.

### BRIEF DESCRIPTION OF THE DRAWINGS

The above and other features and advantages of the present invention will become more apparent by describing in detail exemplary embodiments thereof with reference to the attached drawings in which:

FIG. 1 is a hysteresis loop curve showing polarization versus voltage of a ferroelectric semiconductor material contained in a memory cell of a nonvolatile semiconductor memory device according to an embodiment of the present invention;

FIGS. 2A and 2B illustrate stable polarization states of a ferroelectric semiconductor pattern;

FIG. 3 is a construction diagram of a memory cell array of the nonvolatile semiconductor memory device according to the present invention; and

FIG. 4 is a plan view illustrating a method of writing data in or reading data from memory cells of the nonvolatile semiconductor memory device shown in FIG. 3.

### DETAILED DESCRIPTION OF THE INVENTION

The present invention will now be described more fully with reference to the accompanying drawings, in which exemplary embodiments of the invention are shown. This invention may, however, be embodied in many different forms and should not be construed as being limited to the embodiments set forth herein. Rather, these embodiments are provided so that this disclosure is thorough and complete and fully conveys the concept of the invention to those skilled in the art. In the drawings, the thicknesses of layers may be exaggerated for clarity, and the same reference numerals are used to denote the same elements throughout the drawings.

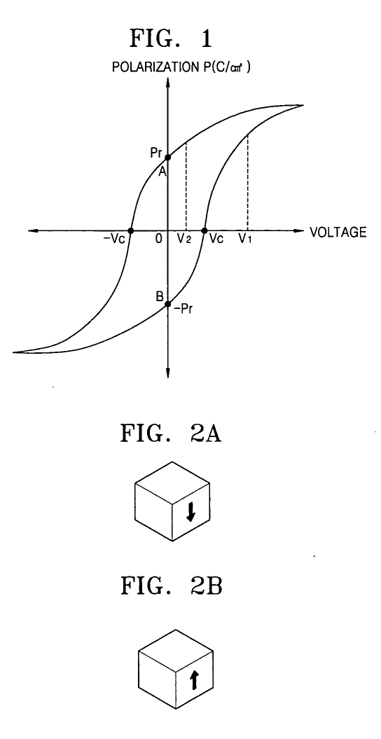

FIG. 1 is a hysteresis loop curve showing polarization versus voltage of a ferroelectric semiconductor material contained in a memory cell of a nonvolatile semiconductor memory device according to an embodiment of the present invention. For example, the ferroelectric semiconductor material may be CdZnTe.

Referring to FIG. 1, it can be seen that CdZnTe shows a stable double polarization state A and B. Here, remnant polarizations are Pr and −Pr, respectively. When the CdZnTe is in a stable polarization state, if a coercive voltage Vc or more is applied to both ends of the CdZnTe, the stable polarization state can be changed. For example, when CdZnTe is in the state B, if a higher voltage V₁ than the coercive voltage V_{c} is applied and removed, the CdZnTe is turned into the state A. However, when the CdZnTe is in a stable polarization state, even if the coercive voltage V_{c} or lower is applied, the stable polarization state is not changed. For instance, when the CdZnTe is in the state B, even if a lower voltage V₂ than the coercive voltage V_{c} is applied and removed, the CdZnTe is not turned into the state A but remains in the state B.

FIGS. 2A and 2B illustrate stable polarization states of a CdZnTe pattern corresponding to the stable double polarization state A and B, respectively. FIG. 2A illustrates the state A, and FIG. 2B illustrates the state B.

As described above, when a ferroelectric semiconductor material, such as CdZnTe, forms a Schottky contact with a certain metal layer, a contact resistance therebetween varies with a polarization direction of the ferroelectric semiconductor material. That is, the contact resistance has two different values at the Schottky contact according to the polarization direction. For example, it is assumed that a Schottky contact is formed between a top surface of a CdZnTe pattern and a certain metal. Here, when a polarization direction of the CdZnTe is the same as a direction of an electric field applied to the CdZnTe as shown in FIG. 2A, a contact resistance between the CdZnTe pattern and the metal is relatively low. Accordingly, a large current flows through the metal and the CdZnTe pattern. Inversely, when the polarization direction of the CdZnTe pattern is different from the direction of the electric field applied to the CdZnTe as shown in FIG. 2B, a contact resistance between the metal and the CdZnTe is relatively high. Thus, a small current flows through the metal and the CdZnTe. Therefore, the state A refers to a low resistance state, while the state B refers to a high resistance state.

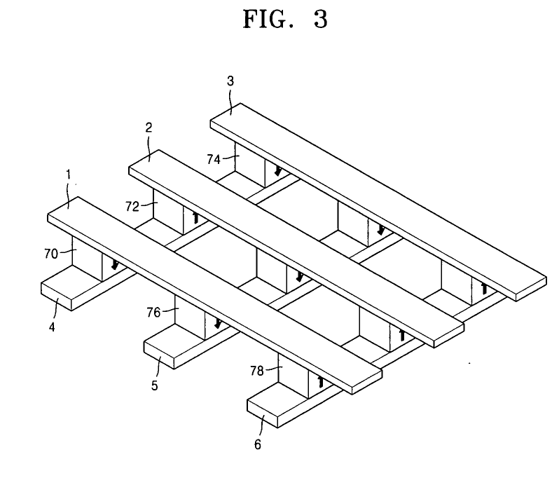

FIG. 3 is a construction diagram of a memory cell array of the nonvolatile semiconductor memory device according to the present invention.

Referring to FIG. 3, the nonvolatile semiconductor memory device includes a substrate (not shown), a plurality of first conductive lines 4, 5, and 6 disposed in or on the substrate, a plurality of second conductive lines 1, 2, and 3 disposed in or on the substrate, and a plurality of ferroelectric semiconductor patterns 70, 72, 74, 76, and 78.

The substrate may be formed of a wide variety of materials, for example, single crystalline silicon or silicon germanium.

The first conductive lines 4, 5, and 6 and the second conductive lines 1, 2, and 3 may be arranged at predetermined intervals. For example, the first conductive lines 4, 5, and 6 may form word lines, respectively, and extend in a first direction in or on the substrate. Also, the second conductive lines 1, 2, and 3 may form bit lines, respectively, and extend in or on the substrate in a second direction orthogonal to the first direction. The first conductive lines 4, 5, and 6 intersect the second conductive lines 1, 2, 3 to define a plurality of intersection regions.

The ferroelectric semiconductor patterns 70, 72, 74, 76, and 78 are interposed between the first conductive lines 4, 5, and 6 and the second conductive lines 1, 2, and 3 that define the intersection lines. A first memory cell is defined by the first conductive line 4, the second conductive line 1, and the ferroelectric semiconductor pattern 70 interposed between the first conductive line 4 and the second conductive line 1. A second memory cell is defined by the first conductive line 4, the second conductive line 2, and the ferroelectric semiconductor pattern 72 interposed between the first conductive line 4 and the second conductive line 2. In FIG. 3, 9 memory cells, which are defined in the above-described manner, are illustrated.

The ferroelectric semiconductor patterns 70, 72, 74, 76, and 78 are formed of a ferroelectric semiconductor material, such as CdZnTe, ZnCdS, CdMnTe, CdMnS, ZnCdSe, and CdMnSe. A Schottky contact may be formed at an interfacial surface between a ferroelectric semiconductor pattern and the first conductive line 1, 2, or 3, and an ohmic contact may be formed between the ferroelectric semiconductor pattern and the second conductive line 4, 5, or 6. The Schottky contact and the ohmic contact may exchange positions. Whether a Schottky contact or an ohmic contact is formed at an interface between a ferroelectric semiconductor pattern and a conductive line depends on a kind of a metal constituting the conductive line. For example, when an n-type ferroelectric semiconductor pattern contacts an Ag conductive line, a Schottky contact is formed at a contact surface therebetween, and when an n-type ferroelectric semiconductor pattern contacts a Pt conductive line, an ohmic contact is formed at a contact surface therebetween.

The ferroelectric semiconductor pattern 70 has a predetermined thickness, and a resistivity of the ferroelectric semiconductor pattern 70 varies with the thickness thereof. Even if the thickness of the ferroelectric semiconductor pattern 70 is constant, a contact resistance at the interface where the Schottky contact is formed varies with a stable polarization state of the ferroelectric semiconductor pattern 70.

For example, the second conductive lines 1, 2, and 3 are formed of Ag, the first conductive lines 4, 5, and 6 are formed of Pt, and CdZnTe patterns are formed in intersection portions defined between the second conductive lines 1, 2, and 3 and the first conductive lines 4, 5, and 6. In this case, when the CdZnTe patterns are in a polarization state shown in FIG. 2A, that is, in the case of memory cells 70, 74, and 76, the height of a barrier of a Schottky contact is small so that a contact resistance is low. On the other hand, when the CdZnTe patterns are in a polarization shown in FIG. 2A, that is, in the case of memory cells 72 and 78, the height of the barrier of the Schottky contact is great so that a contact resistance is high.

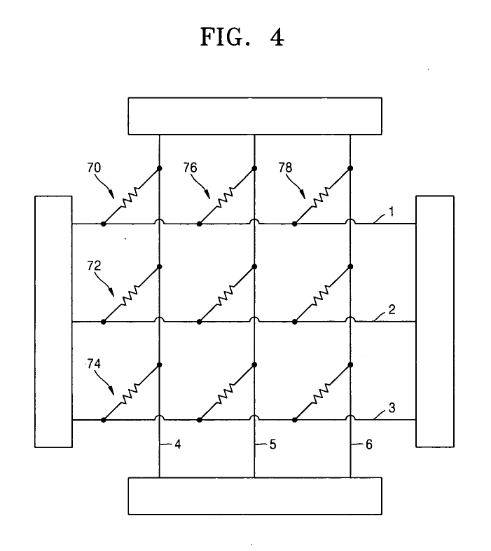

FIG. 4 is a plan view illustrating a method of writing data in or reading data from the memory cells of the nonvolatile semiconductor memory device shown in FIG. 3.

<Write Operation>

A method of writing data in a memory cell of the nonvolatile semiconductor memory device shown in FIG. 3 will be described with reference to FIGS. 3 and 4.

At the outset, to write data 0 in a first memory cell including a ferroelectric semiconductor pattern 70, a higher voltage than a coercive voltage is applied to a selected first conductive line 4, and a selected second conductive line 1 is grounded. In other words, a higher electric potential difference than the coercive voltage is formed forward in the ferroelectric semiconductor pattern 70 of the first memory cell. In this case, a lower electric potential difference than the coercive voltage is formed in or no current flows through the remaining memory cells. Then, the ferroelectric semiconductor pattern 70 of the first memory cell is turned into the state shown in FIG. 2A. The writing of data 0 is enabled irrespective of whether or not data is stored in the first memory cell or what data is stored in the first memory cell.

Next, to write data 1 in the first memory cell of the ferroelectric semiconductor pattern 70, the first conductive line is grounded, and a higher voltage than the coercive voltage is applied to the second conductive line 1. In other words, a higher electric potential difference than the coercive voltage is formed backward in the ferroelectric semiconductor pattern 70 of the first memory cell. In this case, a lower electric potential difference than the coercive voltage is formed in or no current flows through the remaining memory cells. Then, the ferroelectric semiconductor pattern 70 of the first memory cell is turned into the state shown in FIG. 2B. Likewise, the writing of data 1 is enabled irrespective of whether or not data is stored in the first memory cell or what data is stored in the first memory cell.

It is possible to write data in another selected memory cell by applying a forward or backward electric potential difference higher than the coercive voltage to the selected another memory cell. Also, selecting another memory cell can be performed in the same manner as in a conventional semiconductor memory device.

<Read Operation>

A method of reading data stored in a memory cell of the nonvolatile semiconductor memory device shown in FIG. 3 will be described with reference to FIGS. 3 and 4. Here, the first conductive line 1 is formed of Ag and forms a Schottky contact with the ferroelectric semiconductor pattern 70, and the second conductive line 4 is formed of Pt and forms an ohmic contact with the ferroelectric semiconductor pattern 70.

For example, to read data stored in the first memory cell including the ferroelectric semiconductor pattern 70, a lower voltage V_{R} than a coercive voltage of the ferroelectric semiconductor pattern 70 is applied to the first conductive line 1, and the second conductive line 4 is grounded. That is, a lower electric potential difference than the coercive voltage is generated in the ferroelectric semiconductor pattern 70. Even so, since a polarization direction is not changed, data remains stored. Due to the applied electric potential difference, an output current I_{O} that has passed through the ferroelectric semiconductor pattern 70 is output through the second conductive line 4.

The intensity of an output current I_{O} varies with a polarization direction of the ferroelectric semiconductor pattern 70. For example, when data 0 is stored in the first memory cell, since the polarization direction is the same as a direction in which an electric field is applied and a barrier of a Schottky contact is low, a relatively large current Iₘₐₓ flow is output. However, when data 1 is stored in the first memory cell, since the polarization direction is opposite to the direction in which the electric field is applied and the barrier of the Schottky contact is high, a relatively small current Iₘᵢₙ is output. Accordingly, an intermediate value between Iₘₐₓ and Iₘᵢₙ is set to a reference current I_{ref}, and currents output from respective memory cells are compared with the reference current I_{ref}, thus enabling reading of data in the memory cells.

As described above, the semiconductor memory device of the present invention includes a ferroelectric semiconductor pattern in each memory cell, and a resistance of the ferroelectric semiconductor pattern varies with a polarization direction. Even if power supply is abruptly interrupted, the polarization of the ferroelectric semiconductor pattern is neither removed nor changed.

Also, each memory cell of the semiconductor memory device includes neither an active device such as a transistor nor a passive device such as a capacitor. Accordingly, the memory cell having a simple structure can enhance the integration density of the semiconductor memory device.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A nonvolatile semiconductor memory device comprising:
a substrate;
a plurality of first conductive lines disposed in or on the substrate;
a plurality of second conductive lines disposed in or on the substrate and having a different height from the height of the first conductive lines, wherein the second conductive lines intersect the first conductive lines, respectively, to define a plurality of intersection regions; and
a plurality of memory cells disposed on the substrate,
wherein the memory cells include ferroelectric semiconductor patterns, respectively, which are disposed between the first conductive lines and the second conductive lines that define the intersection regions.

2. The device of claim 1, wherein the ferroelectric semiconductor patterns are formed of one selected from the group consisting of CdZnTe, ZnCdS, CdMnTe, CdMnS, ZnCdSe, and CdMnSe.

3. The device of claim 1, wherein a Schottky contact is formed at a contact surface between a ferroelectric semiconductor pattern and one of a first conductive line and a second conductive line, and an ohmic contact is formed at a contact surface between the ferroelectric semiconductor pattern and the other of the first conductive line and the second conductive line.

4. The device of claim 1, wherein each of the first conductive lines forms a word line, and each of the second conductive lines forms a bit line.

5. A method of writing data in a memory cell of a nonvolatile semiconductor memory device comprising a substrate, a plurality of first conductive lines disposed in or on the substrate, a plurality of second conductive lines disposed in or on the substrate and having a different height from the height of the first conductive lines, the second conductive lines intersecting the first conductive lines, respectively, to define a plurality of intersection regions, and a plurality of memory cells disposed on the substrate, wherein the memory cells include ferroelectric semiconductor patterns, respectively, which are disposed between the first conductive lines and the second conductive lines that define the intersection regions, the method comprising writing data in the memory cells by applying a higher electrical potential difference than a coercive voltage of the ferroelectric semiconductor patterns.

6. The method of claim 5, wherein the ferroelectric semiconductor patterns and the first conductive lines form a Schottky contact, and the ferroelectric semiconductor patterns and the second conductive lines form an ohmic contact,
wherein when data 1 is written in the memory cells, a higher voltage than the coercive voltage is applied to the first conductive lines, and the second conductive lines are grounded, and
and wherein when data 0 is written in the memory cells, the first conductive lines are grounded, and a higher voltage than the coercive voltage is applied to the second conductive lines.

7. A method of reading data stored in memory cells of a nonvolatile semiconductor memory device comprising a substrate, a plurality of first conductive lines disposed in or on the substrate, a plurality of second conductive lines disposed in or on the substrate and having a different height from the height of the first conductive lines, the second conductive lines intersecting the first conductive lines, respectively, to define a plurality of intersection regions, a plurality of memory cells disposed on the substrate, and a semiconductor memory device including a plurality of comparison current generating circuits disposed on the substrate, wherein the memory cells include ferroelectric semiconductor patterns, respectively, which are disposed between the first conductive lines and the second conductive lines that define the intersection regions, the method comprising reading data stored in the memory cells by comparing a current flowing through the memory cells when a lower electrical potential difference than a coercive voltage of the ferroelectric semiconductor patterns is applied to the memory cells with a current generated from the comparison current generating circuits.

8. The method of claim 7, wherein if the current flowing through the memory cells is smaller than the current generated from the comparison current generating circuits, it is read as storage of data 1 in the memory cells, and if the current flowing through the memory cells is larger than the current generated from the comparison current generating circuits, it is read as storage of data 0 in the memory cells.
